(19) United States
(12) Patent Application Publication
(10) Pub. No.: US 2021/0321075 A1
(43) Pub. Date: Oct. 14, 2021

(54) 3D CMOS Image Sensor and Imaging Device Design, Process, and Method

(71) Applicant: Linyong Pang, Monte Sereno, CA (US)

(72) Inventor: Linyong Pang, Monte Sereno, CA (US)

(21) Appl. No.: 16/873,734

(22) Filed: Jun. 17, 2020

Related U.S. Application Data
(60) Provisional application No. 63/100,968, filed on Apr. 9, 2020.

(51) Int. Cl. H04N 13/207; H01L 27/146; G02B 27/42; H04N 5/374; H04N 13/257; H04N 9/04

(52) U.S. Cl. CPC H04N 13/207; H01L 27/14627; H01L 27/14621; H01L 27/14645; G02B 5/201; H04N 5/374; H04N 13/257; H04N 9/0455; G02B 27/4205

(57) ABSTRACT

A 3D image sensor based on standard Complementary Metal Oxide Semiconductor (CMOS) process is described. The conventional CMOS image sensor measures a 2D projection of the 3D world in gray-scale or color image; this new sensor can measure the third dimension on the 2D image—the depth of object on the 2D image pixels. Since the standard CMOS image sensor can only sense intensity (the number of photons) at each CMOS pixel, this new sensor creates a new mechanism to encode the depth information into an intensity distribution change that CMOS sensor can sense. The idea is based on the observation or lens imaging theory that light cone for any point (pixel) on the image plane is narrower for a near object and wider for a distant object. We then use diffraction to measure the change of incident angle, based on the theory that an oblique light goes through a finite grating producing diffraction patterns multiple times from near field to far field, the incident angle is reflected as diffraction pattern shift. We use a normal CMOS patterning process to create gratings on top of photosensitive material, and place multiple pixels at a certain distance from the gratings to sense the intensity distribution change or shift for different light cones. Then the depth can be calculated by solving the imaging inverse problem. The solution or intermedium solution of such an inverse problem can be pre-calculated or pre-calibrated and placed in lookup tables so that the image sensor can output directly depth information from the 3D CMOS image sensor.

### TECHNICAL FIELDS

This invention is in the 3D sensing field, in particular, image sensing of the third dimension, depth, on top of the 2D image sensing.

### BACKGROUND

Three-dimensional (3D) computer vision has vast applications, especially in the AI era. VR, AR, digital photography, Robotics, Simultaneous Localization and Mapping (SLAM), 3D reconstruction, face reorganization, bill pay based on 3D face recognition, and gesture recognition all require 3D vision.

The current image sensors are CCD (charge-coupled device) and CMOS (complementary metal-oxide semiconductor) sensor. Both are two-dimensional image sensor arrays that are placed at the image plane of an imaging system (camera) to capture the 2D projection of the 3D world. Both are using photosensitive materials to sense the number of photons collected in the pixel area. A CCD image sensor converts photons into a current, then moves the current out for measurement, while CMOS image sensor converts photons into voltage, measure voltage at the pixel location. The CMOS image sensor has become the mainstream of the image sensor because it can be manufactured using the standard CMOS process that makes most semiconductor chips (CPU, GPU, DRAM, FLASH memories).

Currently, there are three major approaches to obtain the 3^{rd} dimension (depth) from 2D image sensors: stereo, structured-light, and ToF (time of flight). A stereo camera has a pair of standard 2D image sensors and obtains the depth information similar to our human eyes: it identifies and matches the location shift, called disparity, between the same object on the images from the left and right camera captured at the same time. Then the depth is the inverse of the disparity. A structured-light camera projects specific patterns to the object, and calculate the depth from the deformation of such patterns observed from a standard 2D image sensor placed at a different location from the pattern projector. ToF camera emits laser light and receives the bounced signal, the directly or indirectly computes the depth from the time of the laser light flight.

Both stereo and structured light are based on triangulation. Both require complicated matching algorithms to match the pattern and recover the depth. A Stereo camera is categorized as a passive stereo camera or an active stereo camera. In a passive stereo camera, the color, grayscale, or texture from the image is used for matching. It works both indoor and outdoor. However, it does not work well for the places lack of textures, such as walls painted with a single color. The active stereo camera was invented to overcome this drawback. It uses a projector (usually infrared light) to project patterns, textures, speckles, onto the scene, so that an artificial texture is created everywhere on the objects for dense depth matching and calculation. Both stereo and structured light require baseline—placing the second camera in stereo or the projector in structured light away from the camera. The depth range and accuracy are related to the baseline length, larger the baseline, larger the depth range, or more accuracy of the depth can be calculated. Such a baseline requirement limits stereo and structured light in some applications that prefer a very compact size or no baseline.

ToF, on the other hand, doesn't have a baseline. It also requires a light projector, but the light projector can be placed next to the ToF image sensor. Therefore, it fits for applications that require a compact size or no baseline. ToF does not base on triangulation; it is based on the time of light (from the projector) flies to the objects, reflected, and flies back to the ToF image sensor.

ToF has direct ToF (dToF) and indirect ToF (iToF): in dToF the light projector sends out pulses in a very high frequency, in which a special sensor can distinguish each pulse and count the accumulated light dots. By look at the histogram of the light dots, it can interpolate the distance.

In iToF the light projector sends out modulated continuous light, such as sing wave or step functions. For objects in different depths, the modulated light received back at the sensor is different. It converts the distance into a frequency that a special receiver can receive and distinguish. Then from the frequency to map back to distance. Since the modulation is periodic, the sensor will receive the same signals for object more than integer times of the light can travel for each period of the modulation, causing phase wrap, or limit the depth range to a limited range (a couple of meters in most cases). ToF doesn't use triangulation, therefore, the accuracy is about the same within the measurable depth range, about a few millimeters to centimeters. The depth accuracy from ToF cannot match the depth accuracy of stereo and structured light in near range, where they can achieve sub millimeters but can be better than stereo and structured light for longer range.

Stereo, structured-light, and ToF are all trying to convert or encode depth information into something that a sensor can measure. Stereo and structured-light convert the depth into pixel shift, while ToF converts the depths into a super-fast light pulse accumulation in dToF and phase/frequency change in iToF.

Stereo and structured-light are leveraging the massively produced CMOS image sensor. ToF, in general, requires a special semiconductor senor, although there are ways to use the CMOS process to create their receivers. Stereo, structured-light, and ToF all benefit from a light projector, but light projectors are required in structured-light and ToF. In general, the light projector in structured light needs to project certain pre-designed patterns, therefore, more complicated than the light project in ToF, which doesn't project patterns, just modulated with a very high frequency.

In summary the current three types of image sensor that can measure depth all have its own advantages and disadvantages, they are all cost more than the massive manufactured CMOS image sensor, some have a lower resolution, some requires more computing power and complicated algorithms, most require active light projectors, some have large form factors and requires calibrations. The challenges in 3D image sensor remain.

### SUMMARY

In our invention, a new CMOS image sensor is created, it still uses the same CMOS manufacturing process, but it can output depth, and in some embodiment, can also product color (RGB) image, or even infrared images simultaneously. This new 3D COMS image sensor and imaging device can be operated in passive mode, which means just with the light from the scene, but it can also be operated with the help of active light—the light projector. This new 3D CMOS image sensor would have the lowest cost (same cost as a single CMOS image sensor), same frame rate as CMOS image sensor, same or almost the same resolution as CMOS image sensor, same form factor, the depth, and infrared image are aligned with the color image, and no active light (i.e., Infrared light dot projector) is required.

In our invention, we convert or encode the depth in a scene into something that a normal CMOS image sensor can measure. A CMOS sensor can measure intensity (the number of photons) with high accuracy. The standard CMOS sensor can sense 256 levels (stored as 8 bits unsigned integer) of intensity changes. It can also use the CMOS sensor array to match the relocation (shift) of the same or similar intensity or intensity distribution (pattern matching).

One way to understand imaging is through light cone: imagine there is a ball, at any location, one can draw a cone from the observation location to the edge of the ball, this is the “light cone.” The lights from any object will form an infinite number of such light cones for an infinite number of observation points no matter whether there is an observer.

When an observation point is fixed, one can move the ball: when the ball is moved closer to the observation point, the light cone becomes wider; when the ball is moved further away from the observation point, the light cone becomes narrower. However, since all objects will form some kind of light cone to the same observation point, all light cones are mixed up.

The way to separate the light cone is through an imaging device. The simplest model for an imaging device is a pin-hole camera. If a small pin-hole is placed at the observation point and a piece of paper (image plane) is placed behind the pin-hole, such setup is wrapped, so that only light reaches the image plane through the pin-hole. Then the extension of the light cone will form behind the pin-hole to the image plane. Therefore, the angle of the light cone on the image plane is different for an object at a different depth.

Modern imaging devices use a lens to replace the pin-hole. The lens bends the incident angle of the light based on the angle of the two surfaces of the lens because the reflective index of the lens material (usually glass, which is silicon dioxide) is different from the air: At the center of the lens, two surfaces are parallel, the light going through it bends less, while the further from the center, the two surfaces have a bigger angle Therefore, the light going through it bends more. The lens is designed so that all light rays from a single point of an object that goes through different locations on a lens reach a single point on the image plane.

Since the “bending power” on a lens is fixed, the further of the object, the incident angle from one point on the object to the edge of the lens will be smaller, the narrower of the “light cone,” then after it is bent by the lens, the light cone at the image plane for this point is wider; the near the distance of the object, the incident angle from one point on the object to the edge of the lens will be bigger, the wider of the “light cone,” then after the lens bends it, the light cone at the image plane for this point is narrower.

Therefore, at each point of the image plane, the depth is encoded or reflected by the narrowness or wideness of the light cone.

The normal CMOS image sensor can only sense the intensity of the light, the number of photons reaches the pixel area, not light direction.

This invention leverages a property of diffraction gratings. The same light ray with varying the incident angle produces a shift on its diffraction pattern after the gratings. In addition, the diffraction light forms different patterns multiple times from the gratings near field to far field. For a finite grating, the peaks of the diffraction pattern start from the same number as the number of grating periods, reduced when distance increases and eventually becomes 1 in grating near field and far field.

In this invention, a finite grating is placed before light rays reach the photo receiving section of CMOS image pixel. For a different angle of the incident light to the gratings, the shift of diffraction peak is different. The final intensity distribution is integral or superposition of all light rays in the light cone; therefore, for different light cones the final intensity distribution of the diffraction pattern is different. Multiple pixels are placed at a certain distance from the finite grating, where the interference patterns form, to collect the light cone intensity distribution after diffraction. Once such diffraction pattern intensity distribution is collected, the depth can be calculated by solving the inverse problem—from intensity distribution back to light cone angle, from light cone angle to distance of the object. Such multiple pixels to sense diffraction pattern intensity distribution is called one unit of “depth pixel.”

In some of the implementations, a finite grating for one unit of depth sensor is placed before pixel light sensitive material at a certain distance that three diffraction pattern peaks are formed for incident angle 0 (the light ray enters the gratings perpendicularly). Four CMOS sensor pixels are placed right here to collect the diffraction pattern distribution for the 0 order and the two 1st order diffraction peaks.

In some implementations, two CMOS pixels are used at these 3 diffraction peak locations to collect the light cone diffraction distribution.

In some different implementations, the multiple CMOS pixels can be placed at multiple locations that diffraction patterns form, from the same number of the finite grating period, all the way to 3, 2, and 1.

In some implementations, the finite grating can be placed after the CMOS image sensor color filter. This makes the light reaching the grating has a single wavelength or narrow distribution of wavelength.

In some implementations, the normal color channel pixel intensity is calculated by the integral of such multiple pixels of one depth sensor. Therefore, such depth pixels can also output the normal color or grayscale. An approximation of such integral is the sum (or average) of the intensity of pixels in such a depth pixel.

In some implementations, the finite grating can be placed for different CMOS image sensor color filter. The grating properties, such as but not limited, period and duty cycle, height, can be designed so that they all form the same diffraction patterns at the CMOS image pixels. Each color depth sensor can calculate the depth. Multiple color channels can improve depth resolution and robustness.

In some implementations, multiple depth pixels with the same color can be combined to improve depth resolution and robustness. In such cases, either the grating properties, such as period, duty cycle, height, can be designed to form either the same number or a different number of diffraction patterns at the same distance, or phase shift gratings are used, and each depth pixel has a phase offset comparing to others.

In some implementations, the finite grating can be placed behind a color filter that only allows infrared light passes. One can modify the color filters currently used in CMOS image sensors to filter red, green, and blue colors, to filter infrared light.

In some implementations, 4 pixels in a row can be used to form one unit depth pixel for infrared, red, green, and blue, a totally of 4 rows. Such 4×4 pixels can form one unit of a super pixel. Such super pixel can output normal color in red, green, and blue, plus infrared, plus depth. This not only adds infrared and depth channel to each pixel, but also makes all color and depth output automatically aligned and have the same resolution, eliminating the image alignment step that required when combining color image sensor and depth sensor, such as some active stereo and all structured-light, and also in ToF when color image is needed (ToF can only output gray-scale image in addition to depth map).

In some implementations, rows or columns of depth pixels are combined with normal CMOS image sensor color pixels. For example, in a 3×3 super pixel, 2 rows or columns are made by two depth pixels with 3 pixels, the other row or column is made by three normal CMOS image sensor color pixels: red, green, and blue, each with one pixel.

In some implementations, the 4 sub-pixels for a CMOS RGB color pixel, one red, two green in diagonal location, and blue, can be re-arranged. 2 green pixels are placed in a row or a column, a corresponding finite grating is placed on top of the two adjacent green pixels. Such two green pixels can output normal green intensity and depth information. Such implementation can add depth without reducing the normal color CMOS image sensor resolution.

In some implementations, the gratings can be implemented using CMOS metal layer process. The metal (copper) can be to block the light. This is called a binary grating.

In some implementations, the gratings can be implemented using CMOS process with materials that transparent to light. The grating hole region will be etched so that the whole area has the different depth from the other region. Light going through such gratings will not lose energy, but they still interference with two regions with different depths, which causes the different phases of the light. This is called phase shift gratings.

In some implementations, Front Side Illumination (FSI) process of CMOS image sensor is used. In FSI, the light will go through the microlens, and color filter, both optional, then go through the space between metal layers for semiconductor wiring, then hit the light receiving section, which is made of the photosensitive material. The finite gratings can be implemented on top of metal layers (wiring) of the transistor.

In some implementations, Back Side Illumination (BSI) process of CMOS image sensor is used. In BSI, the substrate is flipped and made very thin. It opens the area for the light receiving section, pixel's sensitive material, and the transistors are placed in the back so that light won't be blocked or affected by metal wiring layers. In BSI, we have more degree of freedom, and the gratings can be implemented on top of the substrate. Materials that are transparent to light, such as photo dioxide, can be used in between to make the distance needed.

In some implementations, the grating layer can be combined with a light shield layer in the current CMOS image sensor.

In some implementations, multiple units of depth pixels are put together to form one super depth pixel, for example, 1×2, 2×1, or 2×2 depth pixels to form one super depth pixel. Within each super depth pixel, the finite grating on each depth pixel can be placed orthogonally. Since one dimensional grating samples the angle of the light cone in one direction, adding an orthogonal direction grating will improve the robustness of the depth and color value.

In some implementations, the finite grating can be placed orthogonally within one unit of depth pixel. For example, in a depth sensor composed by 4×4 CMOS image sensor, the grating in the top or bottom one row of sensors are one direction (vertical holes), the rest of three rows are made by 4 columns of the depth sensor, while the gratings in those depth pixels are in the orthogonal direction (horizontal holes).

In some implementations, a mask is placed next to the lens (either in front or behind) to filter the light passing through the lens. For example, an annular mask is placed so that only the largest incident angle of the light cone is collected to improve depth sensitivity.

### DRAWINGS

FIG. 1 is a schematic view of light cones from any observation point to the same sized objects (ball A and ball B). The further the depth from the observation point, the narrow of the light cone.

FIG. 2 is a schematic view of the light cones in a pin-hole camera model for the same size objects at a different depth (ball A and ball B). The further the depth from the pin-hole camera, the narrow of the light cone.

FIG. 3 is a schematic view of the light cones in a lens camera for the same size objects at a different depth (ball A and ball B). The further the depth from the pin-hole camera, the wider the light cone.

FIG. 4 is an Illustration of a finite grating and plane wave perpendicular to the grating.

FIG. 5 is a schematic view of the intensity near, and far field after a plane wave with 0 incident angle (perpendicular to the gratings) passes a finite grating. It shows that diffraction patterns are formed at a certain distance multiple times. It first forms the same number of intensity peaks as the number of grating periods eventually reduces to 3, 2, and a single peak (the rest peaks are much lower). The grating near field and far field are simulated with rigorous Finite Difference Time Domain (FDTD) simulation by solves the Maxell equation.

FIG. 6 is a schematic view of the grating near field and far field from an FDTD simulation of a plane wave with a different incident angle from 0 degrees to 5 degrees passing through a finite grating in FIG. 5. It shows the oblique incident angle causes a diffraction pattern shift.

FIG. 7 is a schematic side view of CMOS image sensor, where (a) is a schematic side view of Backside Illumination (BSI) process, and (b) is a schematic side view of frontside illumination (FSI) process.

FIG. 8 is a schematic perspective view of depth pixel in this 3D CMOS image sensor, where a finite grating is place at a certain distance on top of multiple CMOS pixel photo receiving section, right underneath color filter (optional).

FIG. 9 is a schematic perspective of placing the finite grating between the color filter and the light receiving section (photosensitive material layer) in both FSI and BSI CMOS image sensors.

FIG. 10 is a schematic view of multiple pixels (2, 3, 4, etc.) placed at certain distances from the finite grating where the multiple fraction pattern peaks are formed, such as 3, 2, or 1, to collect the fraction pattern intensity distribution.

FIG. 11 is a schematic top view of (a) describing a color filter and metal light shield arrangement for a typical CMOS image sensor and (b) one implementation of this 3D CMOS image sensor with a super pixel of 4×4 to output depth, infrared, and color images.

FIG. 12 is a schematic top view of one implementation of this 3D CMOS image sensor with a super pixel of 3×3 to output depth, infrared, and color images.

FIG. 13 is a schematic view showing the minimum of multiple pixels that can collect the fraction pattern intensity distribution, or light cone angle is 2, in which the finite grating has to shift with an offset so that the center of the fraction pattern is not exactly at the center of the two pixels.

FIG. 14 is a schematic top view of (a) A color filter and metal light shield arrangement for a typical CMOS image sensor and (b) one implementation of this 3D CMOS image sensor with a super pixel of 2×2 to output depth map and color images.

FIG. 15 is an schematic top view of (a) A color filter and metal light shield arrangement for a typical CMOS image sensor and (b) one implementation of this 3D CMOS image sensor with a super pixel of 2×2 to output depth map using green and blue pixels and color images without even modifying the color filter mosaic.

FIG. 16. is an schematic view showing a mask that blocks the light with certain shapes of opening to allow light to pass through can be placed in front or behind the lens to change the weight of light distribution in the light cone to the image plane in an image setup

FIG. 17 is the flow diagram showing the method of this depth sensing for one unit of the depth sensor.

FIG. 18 is the flow diagram showing the method for assembling multiple depth sensing units to improve depth resolution and robustness.

### DETAILED DESCRIPTION

In the following detailed description of this invention, we use the same or similar number in different figures to refer to the same element or the same thing.

An image sensor that can sense the depth information, the third dimension on top of the normal two-dimensional projection of the 3D scene is described. This image sensor can be manufactured using the massively produced, the industry standard CMOS process. The normal CMOS image sensor converts the photons to voltage and measures the voltage digitally at each pixel location. Therefore, it measures the intensity of the 3D scene projected to a 2D image plane. In this 3D CMOS image sensor and imaging device, we still use the normal CMOS pixel and circuit to measure the photons collected at each pixel area—the pixel intensity, but we are modulating the light so that the depth information can be encoded into in intensity distribution in a small number of pixels. Once such distribution is collected, we can solve the inverse problem to calculate the depth. Such encoding is through two steps: the first step is to encode the depth into the light cone angle. The light cone angle is transferred or enhanced through an imaging setup (pin-hole camera, a camera with a lens or multiple lenses) to the image plane. We can use gratings to bend the light. We leverage the facts 1). the light passing through a finite grating will interference and produce diffraction patterns at multiple locations, and the number of diffraction peaks will gradually reduce from the number of periods on the finite grating to 3, 2, eventually 1, 2). The oblique incident angle will produce a shift on its diffraction pattern from near field to far field; therefore, the light cone angle can be encoded into an intensity distribution, such intensity distribution can be collected by multiple normal CMOS sensor pixels.

The benefits of such a 3D CMOS image sensor and imaging device are many. The first and the most significant aspect is the economic benefit: this sensor can be made with the industry standard and massive produced CMOS process; therefore, the cost is the same or similar to normal 2D CMOS image sensors.

The second benefit is its size: It can be made with the same size as the current color CMOS image sensor in some implementations, therefore, the smallest size among all image sensors, not just 3D image sensor, but also all 2D image sensors. This makes it perfect for applications that require compact size, like cell phones.

The third benefit is that it works in passive mode. Since it is using the light cone angle to encode the depth, it can measure and calculate depth as long as the image sensor “sees” the scene. This means it does not need active light. Therefore, it consumes minimum energy. This is particularly useful for wearable devices, and VR and AR glasses, and even cell phones. In a dark environment, this 3D CMOS image sensor and imaging device need light to light up the scene. This can be done visibly to human eyes or non-visibly to human eyes, like using infrared light. Even in such case, comparing to the active light used in active stereo, structured light, and ToF, it does not require the light with certain patterns like inactive stereo and structured light, nor requires the light pulsed and synchronized with the camera sensor like in ToF, just a normal infrared light will work, therefore much simpler and cheaper than other active depth sensors.

The fourth benefit is it can output both depth and normal intensity or color image at the same time. Since we only use diffraction to redistribute the energy passing through the finite grating, the integral or the summation of the distribution is the normal intensity so that the depth pixel arrangement can produce the normal intensity with the depth.

The fifth benefit is related to the fourth benefit: the depth map and intensity (or color) map is automatically aligned by construction. This is a great benefit for many applications that require the depth map aligned with a color map, such as 3D reconstruction, VR, AR, simultaneous localization, and mapping (SLAM).

The sixth benefit is related to the second benefit: it is a single sensor. Unlike stereo and structured light, two cameras, or the camera and the projector are physically separated; therefore, it requires calibration before usage and requires self-calibration during usage from time to time to maintain its accuracy.

The seventh benefit is that the depth can be output directly from the sensor with a built-in Image Signal Processor (ISP). No extra chip for computing is needed. Not like stereo and structured light, which requires a separated computing unit to do pattern matching, the depth calculation from such a 3D CMOS image sensor and the imaging device is much simpler. Although it requires solving an inverse problem, it is similar to in iToF, which encodes the depth into phase change. The depth is encoded in a couple 8 bit intensities. This has limited entries, for example, 4 pixels of 8 bit sensors, after normalized with its intensity, have total 256\hat{ }4/256=16,777,216 entries, which can be easily implemented in a look-up table by the integrated ISP. In addition, the change in intensity distribution is proportional to the light cone angle. The light cone angle is proportional to depth. Therefore, for a higher number of pixels, we can always use interpolation to interpolate depth from a smaller look-up-table.

The eighth benefit is related to the seventh benefit: high depth resolution. The depth resolution of such a 3D CMOS image sensor and the imaging device is much higher than other depth sensors, since it minimally uses 2 pixels, so 256×256=65,536 levels of depth. For a typical range of 10 meters depth, this is equivalent to roughly 0.0002 meters (0.2 mm) resolution, much higher than stereo, structured light, and ToF. Since normal intensity have 256 levels for 8 bit sensor, we have to normalize the normal intensity, reducing the depth resolution. However, we can increase the number of pixels, and also use different color channels, such as red, green, and blue. These channels have a different wavelength, therefore, different grating design. Their depth results are independent to each other; by combining three color channels together, the depth robustness and resolution can increase 2\hat{ }3=8 times.

The ninth benefit is that this can potentially reduce the reflectivity on CMOS image sensors, therefore enabling smaller pixel size and color sensitivity. When the grating periods is smaller than the wavelength, the grating can absorb all light, letting them pass through, and almost no reflected light.

Before we start describing such 3D CMOS image sensor and imaging device in detail, we want to clarify the terminologies. “Light” is referring to photons; it has wavelength that are visible to human eyes or visible to CMOS image sensors. For example, CMOS image sensor can sense infrared light (wavelength from ^{˜}700 nm to ^{˜}1500 nm), although we humans cannot see it. Many other technical terms will be defined and explained in the context.

### Depth Sensing Principle and Theory

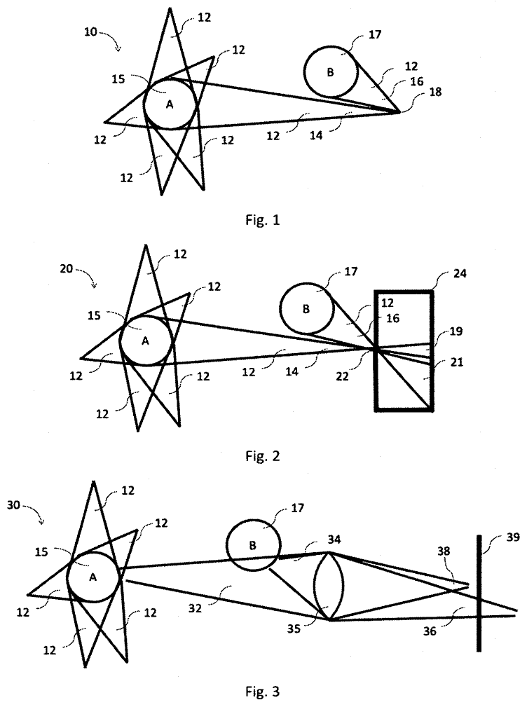

Leonardo Da Vinci first described the imaging theory in the following words: “Everybody in the light and shade fills the surrounding air with infinite images of itself; and these, by infinite pyramids diffused in the air, represent this body throughout space and on every side.” He uses these words to describe the relationship between objects' light and image formation. In fact, pyramids he refers to are not pyramids, but cones. So, it is typically referred to as “light cones.” As shown in FIG. 1, from the same observation point 18 to observe the same object, in this example, is a ball (15 and 17), when you move the light cones further away from the observation point 18 (from 17 to 15), the angle of the light cone 12 becomes smaller (14 is smaller than 16). In other words, the further the depth, the narrower the light cone.

We need an “imaging setup” to project the 3D scene into a 2D image. Here the “imaging setup” usually is called a camera, which includes a box that blocks the light from the environment, only opens a small area; it could be a pin-hole, a lens, or multiple lenses, to allow the light to go through. There is also “lensless” imaging setup, in such setup, the object, usually emitting light by itself, is placed in a black box, and it emits the light directly to the image sensor. The image sensor directly senses the light rays from the object and forms the image.

For pin-hole imaging setup 20, as shown in FIG. 2, the light cone at the pin-hole location (14 and 16) passes the pin-hole 22 and forms an inverse of the light cone (19 and 21), projecting to the image plane. In such an imaging setup, our depth sensing principle is valid: further the depth, the narrower the light cone.

For lens or multiple lenses imaging setups 30, as shown in FIG. 3, it is easier to understand with a reverse of the light cone. Thinking the entire lens area to one point on the object forms a reverse of the light cone (32 and 34). The lens will bend the light. The lens 35 is designed that different regions on lens will bend the light differently. The closer to the lens edge, the light will be bent more, so that light rays from one point on an object and passes the lens will come together to a single point on the image plane. The reverse of a light cone from object to the same lens will have a different light cone angle. Since the lens bend force stays the same for different light, the further the object, the narrower the reverse of the light cone (32 is narrower than 34), the wider the image side of the reverse of the light cone (38 is wider than 36). In other words, the further the depth, the wider the reverse of the light cone at the image plane. In the following for simplicity, we just call it a light cone.

Now we know we can encode the depth information into the angle of the light cone received at the imaging setup image plane. The next is how to measure the wideness or narrowness of the light cone.

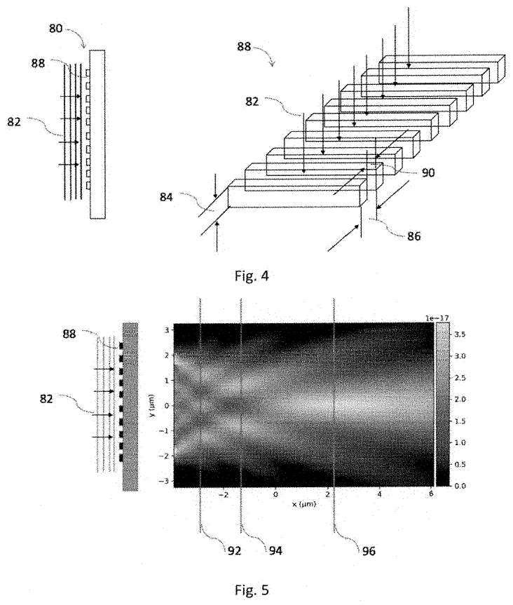

We use gratings and its near field and far field to measure the angle of the light cone. A finit grating 88 is referring to multiple periodic structures that have the dimension around the scale of light wavelength, as shown in FIG. 4. In each period of the structure, the length of the period is 86, the opening area length is 90, and duty cycle is 90/86 in percentage. As shown in FIG. 5, since the structure size is close to wavelength, the light 82 passing through becomes sphere wave, it then propagates, meets the sphere wave from the neighbor structure, since these structures have the same dimension, the wavefront will cause interference, then at some places, the wavefronts from the different periods will add, while at the other places, the wavefronts from the different period will subtract, therefore, it forms patterns, this is called diffraction, the patterns are called diffraction patterns. The diffraction patterns will form multiple times at the different distances. As shown in FIG. 5, for a finite grating 88, means there are a limited number of periodic structures, the number of diffraction patterns will gradually reduce from the same number of periods to 3 (at location 92), 2 (at location 94), and 1 (at location 96). This is because the oblique direction in the sphere wave will propagate to the side and will not contribute to interference anymore. When the distance is at around the order of the grating period, where the number of diffraction patterns forms start from the number of periods, it gradually reduces to 3, 2, and 1, it is call-grating near field, and the diffraction is called Fresnel diffraction. When the distance is far larger than the grating period, the diffraction is called Fraunhofer diffraction. In this 3D CMOS image sensor and imaging device, we mainly use the planes that 3, 2, and 1 diffraction pattern peaks are formed in the finite grating near field (92, 94, and 96), as shown in FIG. 5.

In this 3D CMOS image sensor and imaging device, we use finite grating and diffraction patterns at a certain distance, especially at the places where a small number of diffraction peaks are formed, such as 3, 2, or 1. At those places, we just need a small number of sensing units to sense and measure diffraction pattern changes.

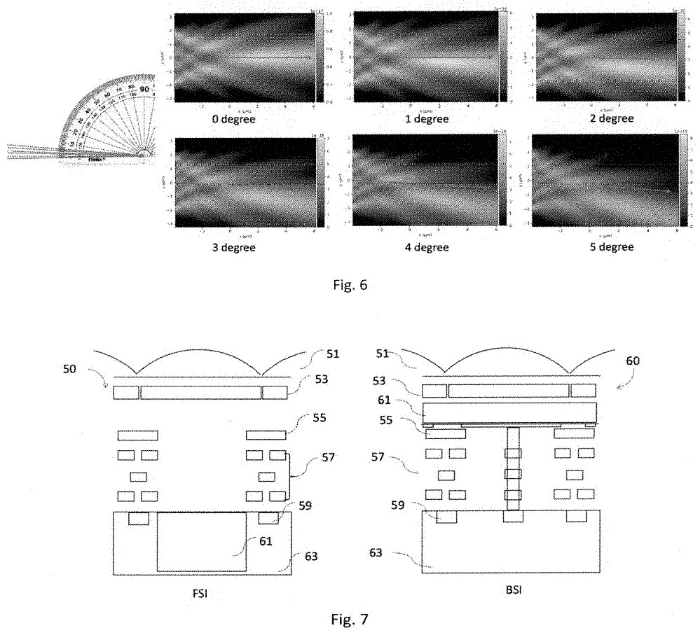

In this 3D CMOS image sensor and imaging device, we leverage another property of gratings and diffraction—its sensitivity to the incident angle. When the incident becomes oblique, the diffraction pattern will change, they still form on the same distance to the grating, but they shifted, as shown in FIG. 6. In other words, the diffraction amplifies the incident angle. The bigger the incident angle, the bigger shift of the diffraction pattern. The light cone means there is light from a symmetric incident angle. The wider the light cone, the bigger shift of the diffraction pattern. Therefore, by collecting the diffraction pattern distribution change, we can measure the light cone angle. Since depth is encoded in the light cone angle, we can sense the depth by measuring the diffraction pattern distribution.

### 3D CMOS Image Sensor

This 3D CMOS image sensor is built with a standard CMOS image sensor process. There are two types of CMOS image sensor structure and process, Front Side Illumination (FSI) and Back Side Illumination (BSI), as shown in FIG. 7. The difference is whether the transistor circuits are placed in the middle of the light path to the photosensitive layer—light receiving section 61.

In FSI (50 in FIG. 7), usually, the light will first pass a microlens 51 (optional); the purpose is to collect the light from the entire pixel area to the area with the light receiving section because the rest of the pixel area is used for circuits. The light then passes the color filter 53 (optional, only for color CMOS image sensor), now it reaches the CMOS circuits. Since in CMOS the transistors and capacitor 59 have to be connected in a certain way to form the circuit, such connections are implemented using multiple layers of metal wiring. These layers are called metal interconnect 57. Usually, there is a metal light shield 55 on the top of the metal interconnect to block light into the interconnect layers. Once the light passes through the space defined by a metal light shield, it reaches the light receiving section 61. The light receiving section is embedded in substrate 63.

Since in FSI, the light has to go through the circuit, and these metal interconnect layers 57 and circuits take some space in each pixel area, only a portion of the pixel area is used to receive light. The ratio of between such area of receiving light to the entire pixel area is called the filling ratio. Since the circuit does take some area, therefore, the filling ratio is limited, and not high in FSI. The limit the number of photons that can reach the light receiving section, which is a drawback of FSI.

BSI was invented to fix such an issue. In BSI, shown as 60 FIG. 7 the entire CMOS transistors 59 and metal interconnect 57 are flipped back, or put on the back of the photo receiving section 61. In other words, once the light passes through a microlens 51 (optional) and a color filter 53 (optional), it will reach the light receiving section 61. The CMOS transistors 59 and metal interconnect 57 will be placed on the backside of the light receiving section 61, that is why this is called backside illumination. In BSI, there is no metal interconnect and circuit to block the light from reaching the light receiving section. Therefore, the whole pixel can be used to receive photons, higher filling ratio, more photons, better sensitivity, and can use a smaller pixel size.

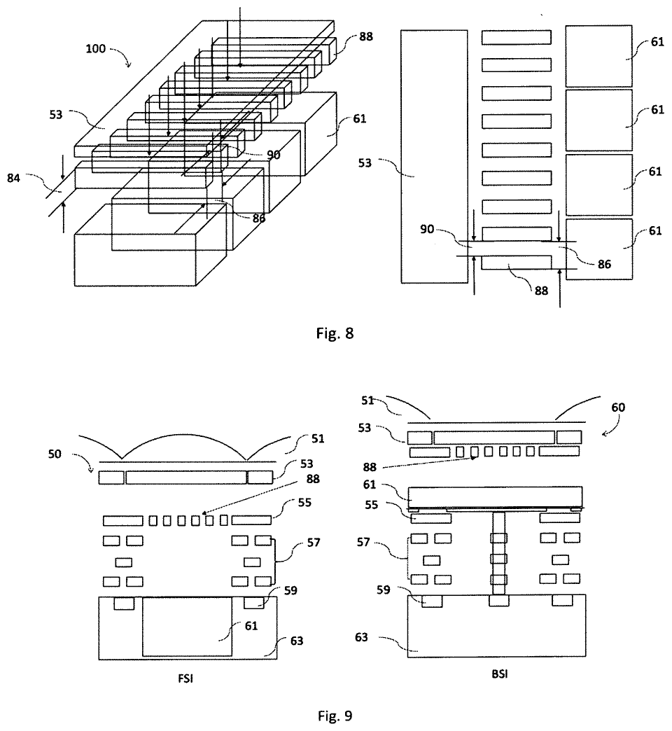

In this 3D CMOS image sensor 100, a finite grating 88 is on top of the light receiving section 61, as shown in FIG. 8. This works for both FSI and PSI. In FSI, as shown in FIG. 9 this finite grating can be implemented using the metal light shield layer 55. In BSI, usually, there is also such a layer to block light crossing pixels. In general, we can use the metal layer process to create such a grating layer 88. The metal layer process can be used to create binary gratings, meaning the metal part will block the light, while the open area between metal wires will allow the light to pass.

One can also make phase shift gratings with only transparent materials, like silicon dioxide. This can be done with the standard CMOS deposition, lithography, and etching process. First, a uniform film of silicon dioxide is created, then certain areas that require different phases are defined by exposing the resist on this silicon dioxide layer, followed by etching to etch down those areas. By controlling the etching time and other parameters, these exposed areas can be made to specified thickness. Usually, the two areas in each grating period are made with the opposite phase (180-degree phase difference), so the light passing through will strongly interfere. The benefit of using phase shift gratings instead of binary gratings is that no energy loss, all light will pass through the layer, therefore, improve sensitivity and also the performance in a low lighting environment.

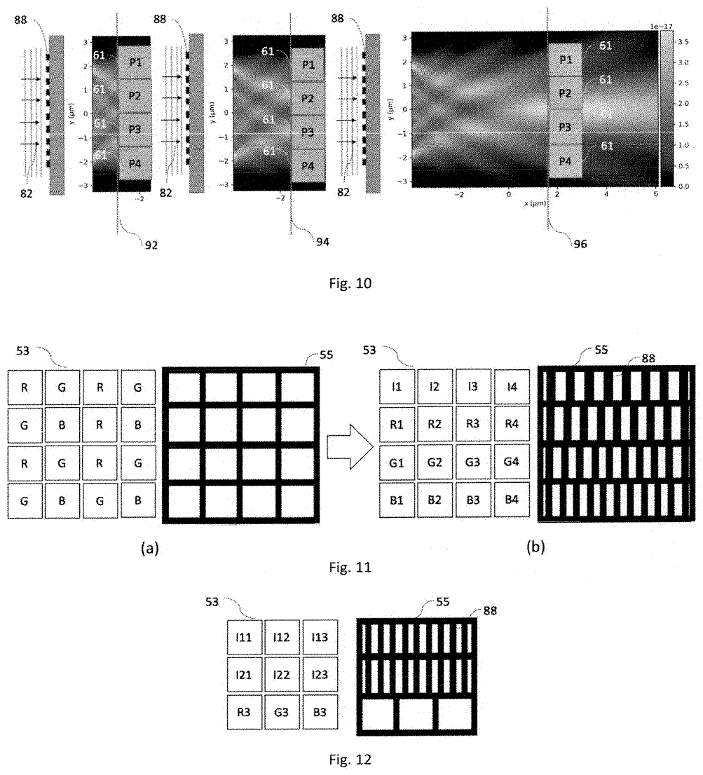

In this 3D CMOS image sensor, multiple CMOS pixels are placed at the selected grating near the field where the diffraction peaks are formed, as shown in FIG. 10. As an example, 4 pixels 61 can be placed at places that 3 diffraction peaks are formed 92, or 2 diffraction peaks 94, or 1 diffraction peak 96. Finite Domain Time Difference (FDTD) is used as a rigorous simulator to determine distance and find the finite grating parameters. FIG. 10 just serves as an example, in a real implementation, the number of pixels and also the distance can vary to fit the need for the application.

Once pixel intensity values are collected, in this example in FIG. 10, P1, P2, P3, and P4, the depth and normal intensity can be calculated.

The light energy passing through the finite grating will keep the energy unchanged; diffraction only changes the energy distribution. There are also some photons reflected from the gratings, but usually, this is less than 1% of the total energy, which can be neglected. Since the energy doesn't change, the normal intensity would be the integral of all pixels. Since each pixel value is already the integration of photons on that pixel, the normal intensity equals the summation of all pixel intensities divided by the number of pixels:

Intensity=(P1+P2+P3+P4)/4

The value for depth can be calculated using the distribution of light intensity P1, P2, P3, and P4. This is an inverse problem to solve; the depth is the inverse solution:

Depth=inverse(P1,P2,P3,P4)

Since there are a limited number of values of P1, P2, P3, and P4, for example, for 8-bit intensity, it is 256 levels. We can build a look-up-table (LUT) to map from the intensity distribution to depth. We can reduce the number of entries of this LUT even further. For example, from diffraction theory and our design the intensity distribution on P1 to P4 are almost symmetric (depending the location of the image pixel in the image plane, the light cone is slightly tilted, but that is a secondary effect, can be ignored), and we also have to normalize on the color intensity, we can reduce the lookup table to

Depth=LUT(UINT 8(P2+P3,P1+P4)*256/2/Intensity)

UINT8 means unsigned 8 bit integer, basically 0, 1, 2, all the way to 255.

For example, a lookup table after calibration may look at this:

LUT (255, 0)=100 m, LUT (254, 1)=94 m, LUT (253, 2)=92 m, . . . . LUT (130, 124)=0.24 m, LUT (129, 125)=0.236 m, LUT(128, 126)=0.233 m, LUT(127, 127)=0.231 m

Please note the resolution of depth is controlled by the size of the look-up-table, which is actually controlled by number of pixels to measure the diffraction distribution in the depth pixel and intensity resolution of each normal CMOS image sensor pixel.

Another way to improve the depth resolution is by adding additional such rows or columns of multiple pixels with different wavelength and the corresponding finite grating design. For example, if one row of 4 pixels is underneath a green color filter, another row next to it can be 4 pixels underneath a blue color filter. The grating period and duty cycle can be calculated by FDTD simulation, so that both rows will form the same number of diffraction peaks at the light receiving section. Since each row can calculate the depth independently, the combined depth resolution will be square of the original resolution.

Another way to improve the depth resolution is by adding additional such rows or columns of multiple pixels with the same wavelength but a different phase. For example, if one row of 4 pixels is underneath a green color filter, another 3 rows next to it can be 4 pixels underneath the green color filter. The finite grating in all 4 rows is made with phase shifting grating with the same period, duty cycle, and aligned. The only difference between rows is the phase, each row is etched in different depth, so that the phase from one row to the next row has an offset, for example, the phase shift for 4 rows is 0 degree, 90 degrees, 180 degrees, and 270 degrees.

In the following, we will show some examples of depth pixel design. They only illustrate some instances based on the principle, not the complete variation of this 3D CMOS image sensor and imaging device.

In some implementation, 4×4 pixels are used to form one superpixel to measure depth, normal color image, and infrared images. As shown in FIG. 11, the typical CMOS color filter mosaic (53 in FIG. 11 (a) is re-arranged: Shown in FIG. 11 (b) A color filter that can filter infrared light (wavelength from 700 nm to 1500 nm, typically 850 nm or 940 nm) is used on top of the 1^{st} row of 4 pixels. The second, third, and fourth row of 4 pixels are underneath red, green, and blue color filters respectively (R for red pixels, G for green pixels, and B for blue pixels). A finite grating 88 with a designed period and a duty cycle is used for each row in order to have the same number of diffraction peaks, for example, 3 peaks formed at the pixel light receiving section layer 61. Each row can be used to compute its own color intensity and depth. The benefits of this 3D CMOS image sensor design are 1). It has high depth resolution because 4 pixels are used in each channel, and 4 channels are used to compute depth independently. 2). The regular red, green, blue values can be computed from the three rows, therefore, it can output the normal color image. 3). It can also output an infrared image since this row with an infrared color filter is added. The downside of this super pixel design is that it uses 4×4 total 16 pixels for one super pixel, therefore, reduce the resolution of CMOS color image sensor by 2 (the typical CMOS color image sensor pixel is composed by 2×2 pixels, 1 red pixel, 2 green pixels, and 1 blue pixel).

What described here is just one example, one can make these pixels in columns instead of row, and one can re-arrange the order of infrared, red, green, and blue color rows.

In some implementation, the depth pixels are combined with normal color pixels. FIG. 12 shows a 3×3 superpixel that can output normal color image, plus infrared image, plus depth map. In this implementation, the first two rows of the color filter 53 are 3 pixels under the infrared color filter. Each row can output an infrared image and depth image (111, 112, 113 and 121,122,123 can output depth independently). One can make phase change, or shift the grating, so that the two infrared gratings become two independent channels to output depth and infrared images. This will improve the resolution and accuracy. The third row has three normal color pixels, red (R), green (G), the blue (B). This implementation has all benefits from the previous implementation plus a smaller superpixel size.

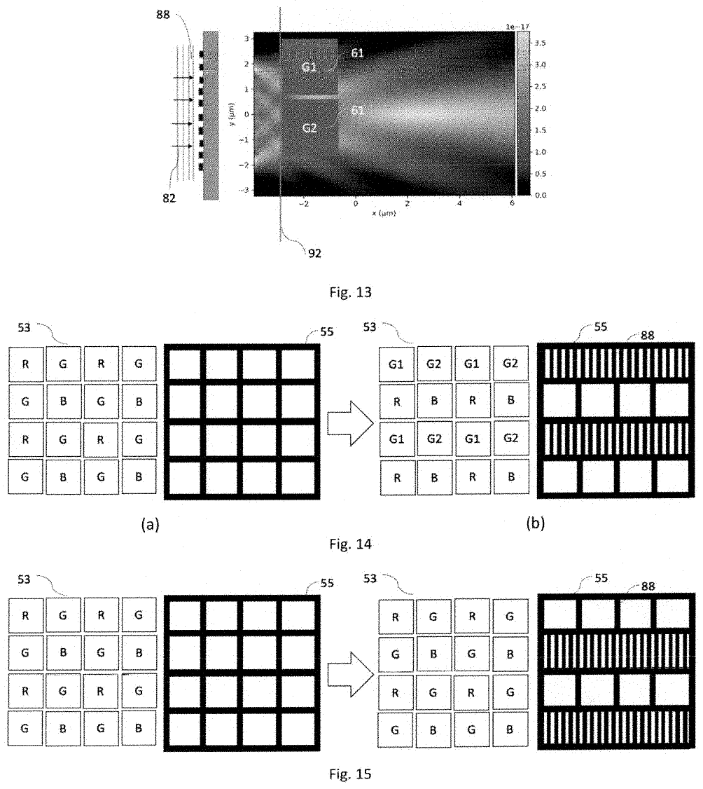

The minimum of multiple pixels that can collect the fraction pattern intensity distribution or light cone angle is 2, in which the finite grating has to shift with an offset so that the center of the fraction pattern is not exactly at the center of the two pixels as shown in FIG. 13. Two depth pixels may not produce high resolution depth, but it can be used to maintain the normal CMOS color pixel size and is useful for certain applications.

In some implementation, adding depth pixels does not need to increase the normal CMOS color image sensor pixel size, while both the depth map and normal color image can be obtained. As shown in FIG. 14, the super pixel is still 2×2, the same as the normal CMOS color image sensor, the color mosaic 53 is changed, for example, the top row two pixels are underneath green color filter (G1, G2), a finite grating 88 is placed on top of these two pixels. The bottom two pixels are underneath the red and green color filters (R and B). In such a configuration the normal green color intensity can be obtained from the sum of two green pixels (G1 and G2). The depth can be obtained from the look-up-table of the two green color pixels (G1 and G2). Red and blue can be obtained from the normal red and blue pixels (R and B).

Again, what described here is just one example, one can make these pixels in columns instead of row, and one can re-arrange the order of red and blue color pixels. One can even choose either red or blue to be the depth pixels, although that may not be optimal.

This implementation may not be the best for depth measurement since it has only two pixels to sense the diffraction distribution. However, it may be perfect for certain applications that do not require an accurate or absolute depth value. For example, this can be used in cell phone cameras to mimic the effect of expensive Single Lens Reflex (SLR) camera, where the background is blurred with a large lens and large aperture. The center of the image is the foreground, the normalized two depth pixel difference will be similar, then those areas will be kept, the rest of the area will be blurred using digital image low pass filters.

In some implementation, not only one can keep the same resolution of the normal CMOS color image sensor, but also keep the color filter mosaic untouched. As shown in FIG. 15, the color filter mosaic 53 is not changed, the finite grating 88 is added on top of the green and blue (R and B) pixels in each 2×2 color mosaic. Although green and blue are different color, their wavelength difference is relatively small, only about 10% difference; therefore, they can be treated the same with some approximation. The benefit of this implementation is that one only need to modifying one photomask for the metal light shield layer in the CMOS manufacturing process to make a normal CMOS color image sensor to have depth sensing capability, because re-arranging color mosaic would require changing of 3 photomasks, which can be expensive. The down side is the blue color will not be accurate any more, but this may not be critical, especially in many computer vision and robotics applications. This implementation is good for upgrading an existing CMOS image sensor process into a 3D CMOS image sensor.

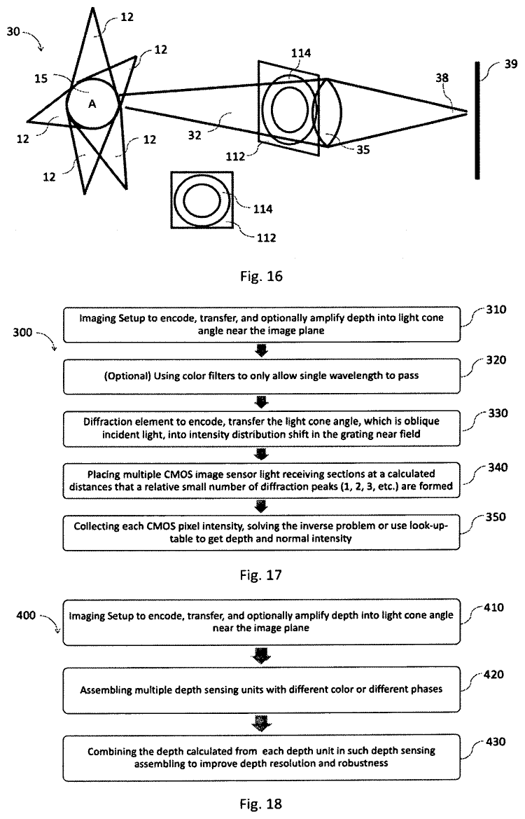

In some implemtation, a mask that blocks light but with certain area of openings to allow light to pass can be placed in front or behind the lens to change the weight of light distribution in the light cone to the image plane. As shown in FIG. 16, a mask 112 with annular shape opening 114 is placed in front of the lens 35 in an imaging setup 30. This mask 112 will block the light close to the center area of the light cone 32, only allow light close to the edge of the light cone 32 to pass into the imaging setup 30 and onto image plane 39. This will change the diffraction intensity distribution, therefore, may enhance the depth resolution. Annular shape is just an example, it could be other shapes, too.

### Methods of 3D Sensing Using Image Cone Angle

The methods of such 3D sensing can be applied to the implementations described above, but can also apply to other variations.

FIG. 17 describes the method for one depth sensing unit 300. In the first step 310, there is an imaging setup. It could be a pin-hole camera, a camera with lens or multiple lenses, or even some lensless setup for an object that emits light itself, that can encode, transfer, or even amplify the depth information into light cone angle to or near to image plane.

In some implementation of 310, a mask can be placed near the lens. It can have opening areas, such as annular openings, that just allow light that close to the edge of the light cone to pass. This can enhance the weight of oblique incident angle in the light cone, therefore, enhance the depth sensing sensitivity.

Then in step 320, optionally, a color filter is placed only to allow the light with certain wavelength to pass. Then, in step 330, at or near the image plane, diffraction elements, such as the finite grating designed above, are used to convert the light cone angle into a diffraction pattern distribution shift. Then in step 340, multiple CMOS image sensor pixels, such as 2, 3, 4, etc., can be placed at a certain location where the finite grating forms a relatively small number of diffraction peaks, such as 1, 2, 3, etc. Then in step 350, the intensity from each CMOS image sensor pixel is collected. The depth can be calculated by solving the inverse problem. Usually, the solution of such an inverse problem can be pre-calculated, pre-calibrated, and stored in a look-up table. The normal pixel intensity can also be calculated, too: in general, it is the integral of the whole diffraction pattern intensity distribution, or in a good approximation, the sum of the intensity of all pixels in a depth unit.

FIG. 18 describes a method to improve the depth resolution and robustness by assembling multiple depth sensing units and method 300. In this method 400, just like in 300, the first step 410 imaging setup does not change. Next step 420 multiple 300 are assembled next to each other. In some implementation, multiple rows of depth sensor 300 with different color filters are packed next to each other. The finite grating parameters, such as period, duty cycle, and depth, are designed according to the wavelength of the color filtered and to make sure they all roughly form the same diffraction peaks at the CMOS image sensor photo receiving section. Since each depth sensing unit output the depth independently, by combining these multiple units, the depth resolution and robustness can be improved. This is step 430.

In some implementation of 400, instead of using depth sensor units with different colors, multiple depth units with the same color but different phases can be used. In such an implementation, usually phase grating is used. The finite grating in each unit are etched with different depth so that the light passing through them have a phase offset (phase shift). By combining the data from multiple channels with phase offset, the depth calculated can have better resolution and robustness.

These implementations are made only to illustrate some cases using this 3D CMOS image sensor and imaging device; numerous modifications can be made from the above implementation examples but still within the principle described in this section.

1. A 3D CMOS image sensor and imaging device of built, using CMOS manufacturing process capable of sensing and outputting a third dimension, a depth, on top of a two-dimensional projection of a scene, comprising
a pinhole, a lens, or multiple lenses to collect the light rays from a scene by projecting an image of the scene to an image plane,
diffraction element capable of diffracting the wavefront of a light into a distribution,
multiple CMOS image sensor pixel photo receiving sections capable of collecting photons to sense a diffraction distribution, the CMOS pixel pitch is bigger than the diffraction element period.

2. The 3D CMOS image sensor and imaging device of claim 1, further compromising color filters before a light wavefront reaches the gratings.

3. The 3D CMOS image sensor and imaging device of claim 1, wherein the CMOS sensor only receives light rays from a scene of interest.

4. The 3D CMOS image sensor and imaging device of claim 3, wherein a lensless setup, adjusted for an object emitting color by itself, sitting in a block box which blocks light from outside.

5. The 3D CMOS image sensor and imaging device of claim 3, wherein a camera setup, a box with a pinhole, or with a lens, or with multiple lenses.

6. The 3D CMOS image sensor and imaging device of claim 1, wherein the diffraction element is a finite grating, a multiple period of gratings on top of each pixel, and it has a finite number of periodic structures, that light will travel differently through it.

7. The 3D CMOS image sensor and imaging device of claim 6, wherein the finite grating is a binary mask: in each period, it has an opening area that light can pass, it also has block areas that light cannot pass, and a duty cycle which is the ratio of the between the opening area dimension and period dimension.

8. The 3D CMOS image sensor and imaging device of claim 6, wherein the finite grating is a phase mask: it is made with materials transparent to light, but with material reflect index different from 1, which is air, and in each period, a certain area has different depth from the other area causing the light to go through it at different times, causing the light coming out from this mask layer having a different phase.

9. The 3D CMOS image sensor and imaging device of claim 6, wherein said finite grating is a one-dimensional structure.

10. The 3D CMOS image sensor and imaging device of claim 9, wherein said one-dimensional grating direction is aligned with the pixel design Manhattan layout, either horizontal or vertical direction for semiconductor design and manufacturing, meeting photomask making and lithography requirements.

11. The 3D CMOS image sensor and imaging device of claim 1, wherein the grating period is close to the wavelength of the light it receives, from 100 nm to 10 um.

12. The 3D CMOS image sensor and imaging device of claim 1, wherein the grating period and duty cycle are designed based on wavelength it receives, the grating period has some correlation to the wavelength in the range from 50 nm to 10 um, and the duty cycle varies around 50% in the range from 5% to 95%.

13. The 3D CMOS image sensor and imaging device of claim 1, wherein gratings are placed at a certain distance from a CMOS image sensor pixel photo receiving section from 10 nm to 10 mm covering grating diffraction near field and far field.

14. The 3D CMOS image sensor and imaging device of claim 13, wherein said distance is chosen based on where the diffraction patterns form in grating diffraction near field, and said distance has a correlation with the period of the finite grating and the wavelength from 10 nm to 10 um.

15. The 3D CMOS image sensor and imaging device of claim 14, wherein the number of diffraction peaks are equal or less than the number of periods in a finite grating.

16. The 3D CMOS image sensor and imaging device of claim 15 wherein said diffraction peaks are 3, 2, or 1 depending on the pixel size and depth sensitivity requirements.

17. The 3D CMOS image sensor and imaging device of claim 1, wherein the multiple CMOS image sensor pixel photo receiving sections arrayed along with one set of finite grating purposed to collect the light distribution and changes, and the number of pixels is chosen based on number of diffracting peaks and depth sensitivity requirements and resolution requirements.

18. The 3D CMOS image sensor and imaging device of claim 17, wherein the range of number of pixels is from 2 to 4.

19. The 3D CMOS image sensor and imaging device of claim 18, wherein 4 pixels are placed at 3 diffraction peak locations, 2 pixels are placed at 1 diffraction peak location, 3 pixels are placed at either 3 diffraction peak locations or 1 diffraction peak location.

20. The 3D CMOS image sensor and imaging device of claim 1, wherein multiple color filters, finite grating, and multiple pixel receiving section form a super pixel, this super pixel can measure depth information, and can also measure color information, the range of such a super pixel can have as small as 2 CMOS image sensor pixel photo receiving sections to as many as 128×128 CMOS image sensor pixel photo receiving sections.

21. The 3D CMOS image sensor and imaging device of claim 20, in one implementation, red, green, blue, and infrared filters are used, each filter has a row or column of 4 pixels underneath to form a super 4×4 unit.

22. The 3D CMOS image sensor and imaging device of claim 20, in one implementation, infrared color filters are on top of 3 pixels in a row or column, then red, green, and blue pixels are placed in the 2 rows or columns next to the infrared row or column to form a super 3×3 unit.

23. The 3D CMOS image sensor and imaging device of claim 22, wherein the finite grating for 3 three infrared pixels are one direction, the finite grating for each two pixels of red, green, and blue are in the other direction.

24. The 3D CMOS image sensor and imaging device of claim 23, in one implementation, two rows infrared color filters are on top of 3 pixels in a row or column, then red, green, and blue pixels are placed in one row or column next to the infrared rows or columns to form a super 3×3 unit.

25. The 3D CMOS image sensor and imaging device of claim 20, in one implementation, green color filters are placed on top of two pixels in a row or column, then red and blue pixels are placed in the row or column next to the green row to form a super 2×2 unit.

26. The 3D CMOS image sensor and imaging device of claim 20, in one implementation, two green color filters are placed at diagonal in a super 2×2 unit, the red and blue are placed at the other two diagonal pixels, each in one pixel, the finite grating is placed on top of either one row or one column.

27. The 3D CMOS image sensor and imaging device of claim 1, wherein gratings with horizontal direction and vertical direction is mixed.

28. The 3D CMOS image sensor and imaging device of claim 1, wherein grating direction inside a super pixel set is mixed.

29. The 3D CMOS image sensor and imaging device of claim 1, wherein a mask is placed in front or behind the lens or multiple lenses, the mask has open areas that only allow larger incident angle light rays to pass, to add the weight of the outer portion of the light cone.

30. The 3D CMOS image sensor and imaging device of claim 29, wherein the mask has an annular shape opening, a disar shape opening, a dipole shape opening, a qusar shape opening, or a quadrapole shape opening.

31. The 3D CMOS image sensor and imaging device of claim 2, wherein color filters that only allows light of certain wavelength pass are used.

32. The 3D CMOS image sensor and imaging device of claim 2, wherein four different color filters are used to filter red, green, blue color, and infrared.

33. The 3D CMOS image sensor and imaging device of claim 2, wherein the color filters are effective at wavelength in the range of 200 nm to 1500 nm.

34. The 3D CMOS image sensor and imaging device of claim 33, wherein the finite grating period and duty cycle are designed based on the color wavelength, the grating period has some correlation to the wavelength, in the range from 50 nm to 10 um, the duty cycle can vary around 50%, from 5% to 95%.

35. The 3D CMOS image sensor and imaging device of claim 2, wherein the same color filter is corresponding to a single set of finite grating and multiple pixels underneath.

36. The 3D CMOS image sensor and imaging device of claim 2, wherein multiple color filters are used, each in a row or column, on top of multiple pixels underneath.

37. A process of making 3D CMOS image sensor and imaging device of built, using CMOS manufacturing process capable of sensing and outputting a third dimension, a depth, on top of a two-dimensional projection of a scene, comprising
a pinhole, a lens, or multiple lenses to collect the light rays from a scene by projecting an image of the scene to an image plane,
diffraction element capable of diffracting the wavefront of a light into a distribution,
multiple CMOS image sensor pixel photo receiving sections capable of collecting photons to sense the diffraction distribution,
the CMOS pixel pitch is bigger than the diffraction element period.

38. The 3D CMOS image sensor and imaging device of claim 37, wherein the CMOS image sensor is manufactured with front side illumination process: the light will go through microlens, and color filter, both optional, then go through the space between metal layers for semiconductor wiring, then hit the light receiving section—the layer of photosensitive material, the finite grating is implemented on top of metal layers of the transistor.

39. The 3D CMOS image sensor and imaging device of claim 37, wherein the CMOS image sensor is manufactured with back side illumination process: the substrate is flipped and made very thin, it opens the area for pixel's photosensitive material layer, and the transistors are placed in the back so that light will not be blocked or affected by metal wiring layers, the light will go through microlens, and color filter, both optional, then hit the light receiving section—the layer of photosensitive material.

40. The 3D CMOS image sensor and imaging device of claim 37, wherein the gratings are made using the metal layer in CMOS process.

41. The 3D CMOS image sensor and imaging device of claim 37, wherein the gratings are made using the materials transparent to light, the two different regions in each period of the finite grating are etched in different depth to form phase shift mask.

42. The 3D CMOS image sensor and imaging device of claim 37, wherein the grating layer is combined with CMOS light shield layer.

43. A method for sensing and outputting depth information using CMOS image sensor comprising the steps of
encoding a depth information into a light cone angle,
using an imaging setup to transfer the light cone into an image plane, electing a certain wavelength using color filter,
using gratings to convert the change in a light incident angle into a shift on its diffraction patterns in the near field and far field,
using a finite grating to form diffraction pattern at a different distance from the number of grating periods to 3, 2, 1. Place multiple CMOS image sensor pixels light receiving section at one of such distances to collect the diffraction pattern distribution intensity and change,
collecting the intensity from each pixel, computing the depth by solving an inverse problem.

44. The method of claim 43, further comprising transferring the light cone into an image plane through a pin-hole camera or a camera with lens or multiple lenses.

45. The method of claim 43, further comprising color filters that pass through red, green, blue, and infrared colors.

46. The method of claim 43, further comprising collecting the fraction pattern intensity distribution using a finite grating on top of multiple pixels.

47. The method of claim 43, further comprising placing the pixel photosensitive layer at the finite grating near field to far field at the distance that diffraction peaks are formed.

48. The method of claim 47, further comprising placing the pixel photosensitive layer at the finite grating near field to far field at the distance that 3, 2, or 1 peak are formed.

49. The method of claim 43, further comprising designing the grating properties, including but not limited to reflect index, period, duty cycle, and height to form diffraction peaks at a certain distance.

50. The method of claim 43, further comprising collecting diffraction pattern intensity distribution from one to sixteen finite gratings to solve the inverse problem to derive depth information.

51. The method of claim 43 is further comprising combining data from multiple finite gratings from different colors to improve the robustness and resolution in depth of information.

52. The method of claim 43, further comprising computing the normal color intensity by integrating the diffraction intensity.

53. The method of claim 43, further comprising by combining data from multiple finite gratings from different shifted phases to improve the depth information robustness and resolution.

54. The method of claim 43, further comprising a pre-stored means of conversion between the diffraction intensity distribution and depth to pre-store the correlation between the diffraction intensity distribution and the depth, so the depth can be output without solving inverse problems every time.

55. The method of claim 54, further comprising leveraging the fact that light cone is close to symmetric, because lens is symmetric, and the CMOS sensor area is relatively small to the lens area, to combine, average pixels values of the symmetric located pixels to reduce the entries of the pre-stored means of conversion between the diffraction intensity distribution and the depth.

56. The method of claim 54, further comprising leveraging the fact that depth is proportional to diffraction distribution change to interpolate, using linear interpolation, or quadratic interpolation, to calculate the depth from smaller pre-stored means of conversion between the diffraction intensity distribution and the depth.

57. The method of claim 43, further comprising having one set finite grating to cover two pixels in a row of color with different color filters, using the superposition of diffractions of two wavelengths to compute depth.

58. The method of claim 43, further comprising placing a mask in front or behind the lens to change the weight of light distribution in a light cone.

59. The method of claim 58, further comprising mask where the outer ring portion is open so that the outer edge portion of the light cone is collected at the image plane.

60. The method of claim 59, wherein the mask has an annular shape opening, a disar shape opening, a dipole shape opening, a qusar shape opening, or a quadrapole shape opening.
